(19) United States
(12) Patent Application Publication
(10) Pub. No.: US 2013/0323044 A1
(43) Pub. Date: Dec. 5, 2013

(54) MOUNTING APPARATUS FOR FAN

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/593,475

(22) Filed: Aug. 23, 2012

(30) Foreign Application Priority Data
May 31, 2012 (CN) 201210175209.2

(51) Int. Cl. F04D 29/64; H05K 7/20

(52) U.S. Cl. 415/213.1

(57) ABSTRACT

A mounting apparatus for a fan includes a bracket, two first fasteners, and a shield plate. The bracket includes a fixing plate defining a vent and two first through holes adjacent to opposite ends of a top of the vent. The first fasteners extend through the first through holes of the bracket, for engaging in an upper portion of the fan arranged behind the fixing plate, with the vent aligning with the fan. Each first fastener includes a head abutting a front side of the fixing plate. A top of the shield plate is rotatably connected between the heads of the first fasteners. The shield plate hangs vertically by gravity to cover the vent upon a condition that the gravity of the shield plate is not overcome by airflow passing through the vent.

### BACKGROUND

1. Technical Field

The present disclosure relates to an apparatus for mounting a fan.

2. Description of Related Art

In electronic devices, fans are mounted to a bracket for dissipating heat produced from the electronic components in the electronic devices. However, when a fan is broken or becomes unmounted, air pressure in the electronic device changes, which will cause turbulence and air to back flow, adversely influencing heat dissipation from the electronic device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of a mounting apparatus together with a plurality of fans.

FIG. 2 is a partial, exploded, isometric view of FIG. 1.

FIG. 3 is an enlarged view of a first fastener of FIG. 2 from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

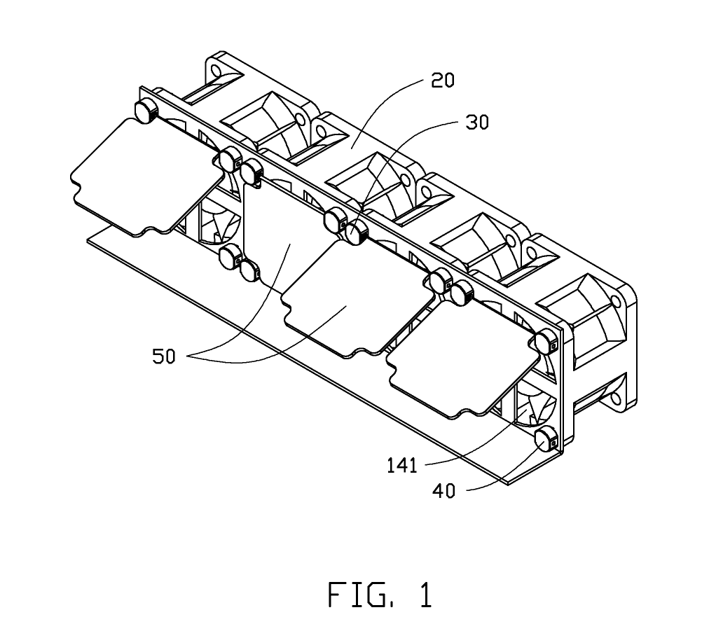

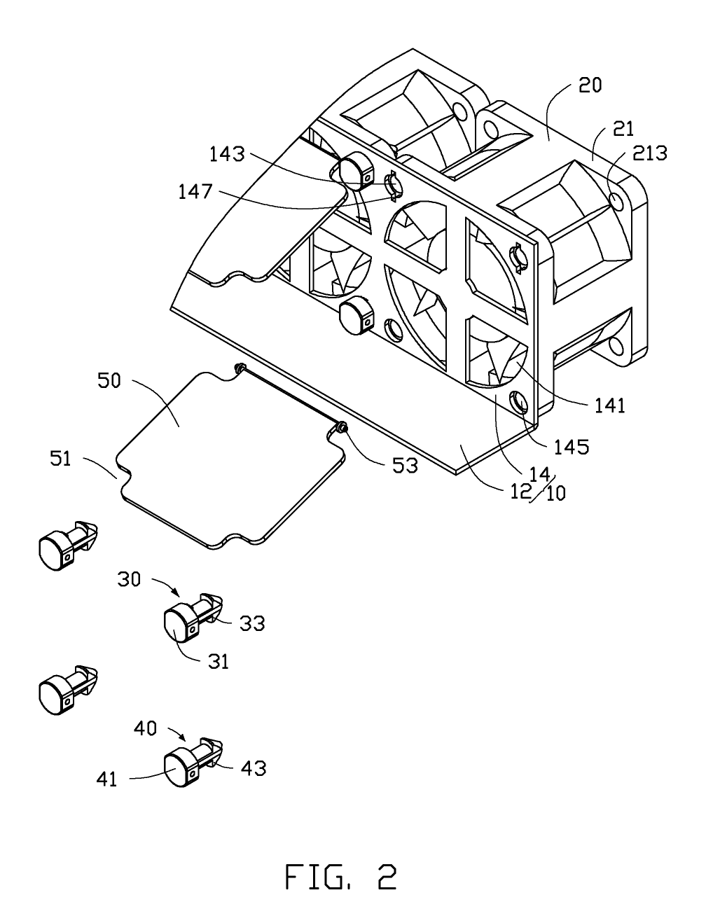

FIGS. 1 and 2 show an embodiment of a mounting apparatus for a plurality of fans 20. The mounting apparatus includes a bracket 10, four pairs of first fasteners 30, four pairs of second fasteners 40, and four substantially rectangular shield plates 50.

Each fan 20 includes two opposite side plates 21. Each side plate defines four fixing holes 213 in four corners thereof.

The bracket 10 includes an elongated base 12, and a substantially rectangular fixing plate 14 extending upwards from a rear side of the base 12 in a substantially perpendicular manner. Four vents 141 are defined in the fixing plate 14, arranged in a horizontal direction. Two first through holes 143 are defined in the fixing plate 14 adjacent to opposite ends of the top of each vent 141, and two second through holes 145 are defined in the fixing plate 14 adjacent to opposite ends of the bottom of each vent 141. Two opposite slots 147 are vertically defined in the fixing plate 14, respectively at the top side and the bottom side of each first through hole 143, communicating with the first through hole 143.

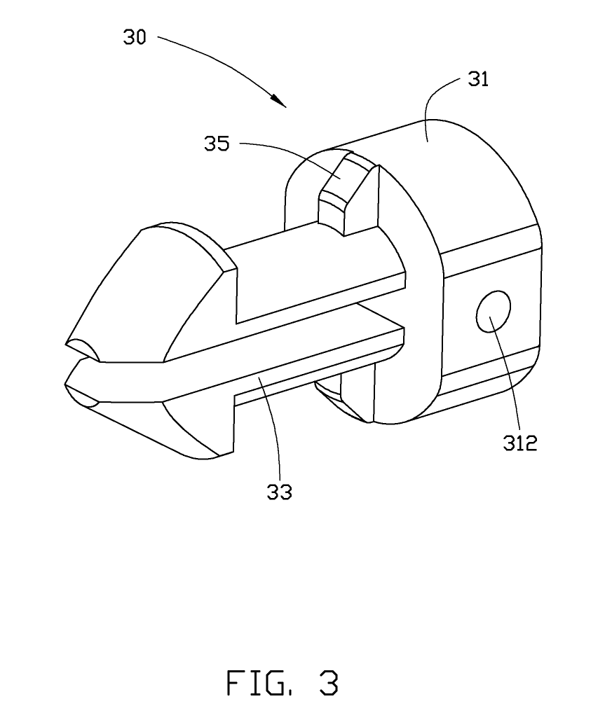

Referring to FIG. 3, each first fastener 30 includes a head 31 and two hooks 33 extending rearward and away from each other from the rear side of the head 31. Two pivot holes 312 are respectively defined in opposite ends of the head 31. Two vertically extending protrusions 35 respectively protrude from an upper section and a lower section of the rear side of the head 31.

Each second fastener 40 includes a head 41 and two hooks 43 extending rearward and away from each other from the rear side of the head 41.

Four notches 51 are defined in four corners of each shield plate 50. Two pivots 53 protrude from opposite ends of the top side of each shield plate 50, extending toward two corresponding notches 51.

To assemble a fan 20 to the mounting apparatus, one of the side plates 21 abuts the rear side of the fixing plate 14, to allow the fixing holes 213 of the side plate 21 to align with two first through holes 143 and two second through holes 145 around one of the vents 141. The hooks 43 of a pair of second fasteners 40 extend through the two second through holes 145 and engage in two fixing holes 213 at a lower section of the side plate 21. The hooks 33 of a pair of first fasteners 30 extend through the two first through holes 143 and engage in two fixing holes 213 at an upper section of the side plate 21. Thereby, the fan 20 is fastened to the fixing plate 14 and aligns with the vent 141. The rear sides of the heads 31 and 41 of the first and second fasteners 30 and 40 abut the front side of the fixing plate 14. The protrusions 35 of the pair of first fasteners 30 engage in the slots 147 around the two first through holes 143, to lock the first fasteners 30 to the fixing plate 14. The pivot holes 312 of the two first fasteners 30 are arranged on a horizontal line.

The other fans 20 are mounted to the mounting apparatus using the same manner, with each vent 141 aligning with a fan 20.

The four shield plates 50 are mounted in front of the four vents 141, to allow the pivots 53 of each shield plate 50 to rotatably engage in the pivot holes 312 of two first fasteners 30 adjacent to opposite ends of the corresponding vent 141. The shield plates 50 hang vertically by gravitational force, allowing each vent 141 to be covered by one shield plate 50. The first and second fasteners 30 and 40 are partially received in the notches 51.

When the fans 20 operate, airflow from the fans 20 passes through the corresponding vents 141 and is blown towards the shield plates 50 right ahead of the fans 20. The shield plates 50 rotate forward 90 degrees around the corresponding pivots 53, to allow the airflow produced by the fans 20 to pass through.

Before a replacement of a broken fan 20 is completed, the shield plate 50 in front of the broken fan 20 vertically covers the corresponding vent 141 by means of gravitational force. Air pressure at the vertical shield plate 50 will not change substantially, so the vertical shield plate 50 can prevent air from flowing back to the broken fan 20.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A mounting apparatus for a fan, comprising:
a bracket comprising a fixing plate defining a vent and two first through holes adjacent to opposite ends of a top of the vent;
two first fasteners extending through the first through holes of the bracket, for engaging in an upper portion of the fan arranged behind the fixing plate, with the vent aligning with the fan, wherein each first fastener comprises a head abutting a front side of the fixing plate; and
a shield plate with a top of the shield plate rotatably connected between the heads of the first fasteners, wherein the shield plate hangs vertically by gravity to cover the vent upon a condition that the gravity of the shield plate is not overcome by airflow passing through the vent.

2. The mounting apparatus of claim 1, wherein each first fastener further comprises two hooks extending rearward from a rear side of the head, the hooks of the first fasteners extend through the first through holes, for engaging in the fan.

3. The mounting apparatus of claim 2, further comprising two second fasteners, wherein the fixing plate further defines two second through holes adjacent to opposite ends of a bottom of the vent, the second fasteners extend through the second through holes, for engaging in a lower portion of the fan.

4. The mounting apparatus of claim 3, wherein each second fastener comprises a head and two hooks extending rearward from a rear side of the head, the hooks of the second fasteners extend through the second through holes, for engaging in the fan.

5. The mounting apparatus of claim 4, wherein the shield plate is substantially rectangular, and four notches are defined in four corners of the shield plate.

6. The mounting apparatus of claim 2, wherein a pivot hole is defined in an end of each head facing toward the opposite head, and two pivots protrude from opposite ends of the top of the shield plate, to rotatably engage in the pivot holes of the heads.

7. The mounting apparatus of claim 6, wherein two slots are defined in the fixing plate, respectively at opposite sides of each first through hole, and two opposite protrusions protrude backward from the rear side of each head, the protrusions engage in the corresponding slots, to lock the first fasteners to the fixing plate.
